(19) United States
(12) Patent Application Publication
(10) Pub. No.: US 2009/0246952 A1
(43) Pub. Date: Oct. 1, 2009

(54) METHOD OF FORMING A COBALT METAL NITRIDE BARRIER FILM

(75) Inventors: Tadahiro ISHIZAKA, Watervliet, NY (US); Shigeru Mizuno, Delmar, NY (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/058,595

(22) Filed: Mar. 28, 2008

(51) Int. Cl. H01L 21/768

(52) U.S. Cl. 438/653; 257/E21.584

(57) ABSTRACT

A method is provided for forming a cobalt metal nitride barrier film on a substrate for semiconductor devices. According to one embodiment of the invention, the method includes depositing a plurality of metal nitride layers on the substrate, and depositing a cobalt layer between each of the plurality of metal nitride layers. According to another embodiment of the invention, the method includes simultaneously exposing the substrate to a metal nitride precursor or a metal precursor, a cobalt precursor, and a reducing gas, nitriding gas, or a combination thereof. Embodiments for integrating a cobalt metal nitride barrier film into semiconductor devices are described.

### CROSS-REFERENCE TO RELATED APPLICATIONS

This application is related to co-pending U.S. patent application Ser. No. 11/839,410, entitled “SEMICONDUCTOR DEVICE CONTAINING AN ALUMINUM TANTALUM CARBONITRIDE BARRIER FILM AND METHOD OF FORMING,” filed on Aug. 15, 2007, the entire content of which is hereby incorporated by reference.

### FIELD OF INVENTION

The field of the invention relates generally to the field of forming a semiconductor device, and more specifically to the use of a cobalt metal barrier film for copper metallization.

### BACKGROUND OF THE INVENTION

An integrated circuit contains various semiconductor devices and a plurality of conducting metal paths that provide electrical power to the semiconductor devices and allow these semiconductor devices to share and exchange information. Within a semiconductor device, metal layers are stacked on top of one another using intermetal or interlayer dielectric layers that insulate the metal layers from each other. Metal layers typically occupy etched pathways in the interlayer dielectric. Normally, each metal layer must form an electrical contact to at least one additional metal layer or conductive layer. Such electrical contact is achieved by etching a hole in the interlayer dielectric that separates the metal layers or a metal layer and a doped substrate region, and filling the resulting via with a metal (plug) to create a vertical interconnect structure. A “via” normally refers to any micro-feature such as a hole, line or other similar feature formed within a dielectric layer that provides an electrical connection through the dielectric layer to a conductive layer underlying the dielectric layer. Similarly, micro-features containing metal layers connecting two or more vias are normally referred to as trenches.

The use of a low resistivity metal such as copper (Cu) provides significant gains in switching delay (RC-delay) and power consumption of integrated circuits. Bulk Cu metal is surrounded by barrier films that separate the bulk Cu metal from dielectric materials and other materials. Cu metal cannot be put in direct contact with dielectric materials since Cu metal has poor adhesion to the dielectric materials and Cu metal is known to easily diffuse into common integrated circuit materials such as silicon and dielectric materials where Cu metal is a mid-bandgap impurity. Furthermore, oxygen can diffuse from an oxygen-containing dielectric material into Cu metal, thereby decreasing the electrical conductivity of the Cu metal. Therefore, a diffusion barrier material is formed on dielectric materials and other materials in the semiconductor device to surround the Cu and prevent diffusion of the Cu into the semiconductor device materials.

However, common diffusion barrier material for Cu metallization have polycrystalline or columnar micro-structures with grain boundaries through which diffusion of oxygen, Cu, and Si can occur, thereby degrading or destroying the integrated circuit. Therefore, micro-structures of diffusion barrier materials need to be controlled to provide improved barrier properties for Cu metallization.

### SUMMARY OF THE INVENTION

A method is provided for forming a cobalt metal nitride barrier film on a substrate for semiconductor devices. The addition of cobalt (Co) into a metal nitride layer can remove grain boundaries and form a cobalt metal nitride barrier film with a substantially amorphous structure for improved resistance to O, Cu, and Si diffusion into materials used in semiconductor devices.

According to one embodiment of the invention, the method includes providing a substrate in a process chamber; and forming a cobalt metal nitride barrier film on the substrate by depositing a plurality of metal nitride layers, and depositing a cobalt layer between each of the plurality of metal nitride layers.

According to another embodiment of the invention, the method includes providing a substrate in a process chamber; and forming a cobalt metal nitride barrier film on the substrate by simultaneously exposing the substrate to a metal nitride precursor and a cobalt precursor, or exposing the substrate to a metal precursor, a cobalt precursor, and a nitrogen precursor.

According to still another embodiment of the invention, a method is provided for forming a semiconductor device. The method includes providing a substrate containing a dielectric film having a recessed feature; forming a cobalt metal nitride barrier film in the recessed feature; and forming bulk Cu metal over the cobalt metal nitride barrier film in the recessed feature.

According to yet another embodiment of the invention, the method includes providing a substrate containing a dielectric film having a recessed feature; forming a cobalt metal nitride barrier film in the recessed feature; forming a Ru metal film over the cobalt metal nitride barrier film; and forming bulk Cu metal over the Ru metal film in the recessed feature.

### BRIEF DESCRIPTION OF THE DRAWINGS

The present invention is illustrated by way of example and not as a limitation in the figures of the accompanying drawings.

FIG. 1 depicts a schematic view of a processing system for forming a cobalt metal nitride barrier film in accordance with an embodiment of the invention;

FIGS. 2-5 schematically show methods for forming multilayer structures containing a cobalt metal nitride barrier film according to embodiments of the invention;

FIGS. 6A-6C show process flow diagrams for forming a cobalt metal nitride barrier film according to embodiments of the invention;

FIGS. 7A-7H schematically show methods for forming a semiconductor device containing a cobalt metal nitride barrier film according to embodiments of the invention;

FIGS. 8A and 8B show additional semiconductor device structures that may utilize a cobalt metal nitride barrier film according to embodiments of the invention;

FIGS. 9A-9C schematically show growth of a polycrystalline metal nitride film; and

FIGS. 9D-9E schematically show growth of a substantially amorphous cobalt metal nitride barrier film according to an embodiment of the invention.

### DETAILED DESCRIPTION OF SEVERAL EMBODIMENTS

Formation of cobalt metal nitride barrier films that may be utilized in Cu metallization for semiconductor devices is disclosed in various embodiments. The cobalt metal nitride barrier film may be formed over a surface of recessed feature in a dielectric layer where the recessed feature may have an exposed metallization layer at the bottom of the recessed feature. According to embodiments of the invention, intermixing of cobalt and metal nitride in the cobalt metal nitride film reduces or prevents polycrystalline or columnar film growth and forms a substantially amorphous structure that provides improved diffusion barrier properties against oxygen, Cu, and Si diffusion, for example. The cobalt metal barrier film can further provide lower electrical resistance compared to the corresponding metal nitride material which results in significant gains in switching delay (RC-delay) and power dissipation in the integrated circuit. Furthermore, the cobalt metal nitride barrier film can provide improved adhesion properties to metal layers such as ruthenium (Ru) and Cu.

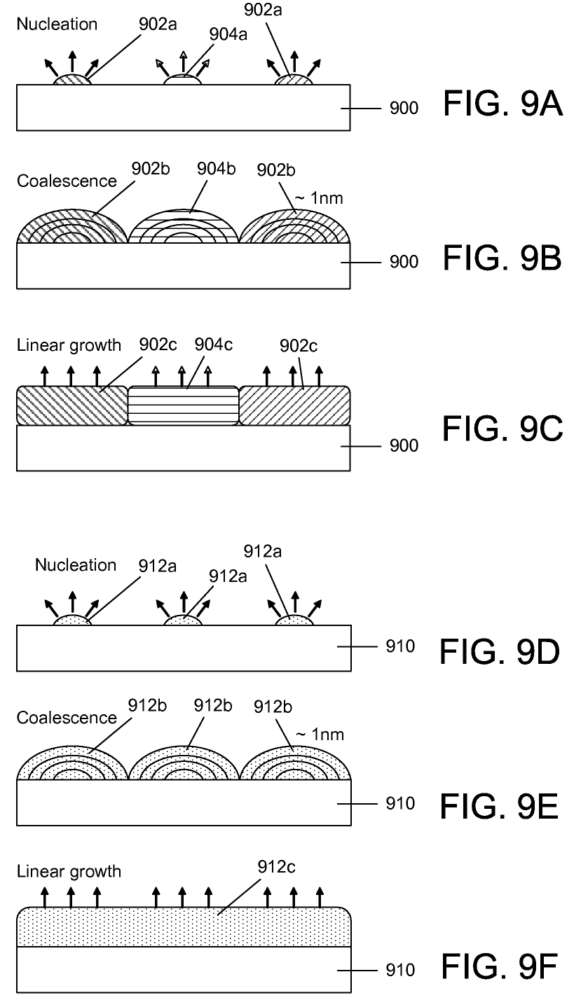

FIGS. 9A-9C schematically show growth of a polycrystalline metal nitride layer. FIG. 9A schematically shows nucleation stage of a polycrystalline metal nitride film containing crystallites 902a having a first crystallographic orientation and crystallite 904a having a second crystallographic orientation that is different from the first crystallographic orientation. FIG. 9B schematically shows coalescence stage of the polycrystalline metal nitride film containing crystallites 902b having the first crystallographic orientation and crystallite 904b having the second crystallographic orientation. A thickness of the polycrystalline metal nitride film can be about 1 nanometer (nm). FIG. 9C schematically shows linear growth stage of the polycrystalline metal nitride layer containing crystallites 902c with the first crystallographic orientation and crystallite 904c having the second crystallographic orientation. The polycrystalline metal nitride layer depicted in FIG. 9c has grain boundaries between the crystallites 902c and 904c that may provide diffusion paths for oxygen, Cu, and Si, for example. In one example, the polycrystalline metal nitride layer may contain tantalum nitride.

FIGS. 9D-9E schematically show growth of a substantially amorphous cobalt metal nitride barrier film according to an embodiment of the invention. FIG. 9D schematically shows nucleation stage of a cobalt metal nitride barrier film containing substantially amorphous nuclei 912a. FIG. 9D schematically shows coalescence stage of a cobalt metal nitride barrier film containing amorphous nuclei 912b. FIG. 9C schematically shows linear growth stage of the cobalt metal nitride barrier film 912c. The amorphous cobalt metal nitride barrier film 912c has less grain boundaries and thereby provides better diffusion barrier properties than the polycrystalline metal nitride film depicted in FIG. 9c.

According to embodiments of the invention, the cobalt metal nitride barrier film can contain metals selected from tantalum (Ta), titanium (Ti), tungsten (W), and other metals suitable for use in diffusion barriers. Furthermore, in addition to nitrogen (N), the cobalt metal nitride barrier film can contain carbon (C), oxygen (O), a halogen (e.g., chlorine (Cl)), and hydrogen (H). In one example, the cobalt metal nitride barrier film may contain a significant amount of C. Films containing both N and C are often referred to as carbonitride films and may contain similar amounts of N and C. In one example, a cobalt tantalum carbonitride barrier film can have Ta:C:N elemental ratios of approximately 2:1:1. In some embodiments, the cobalt metal nitride barrier film can contain at least 5 (and in some embodiments, at least 10, 15, 20, 25, 30, 35, or even at least 40) atomic percent cobalt.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

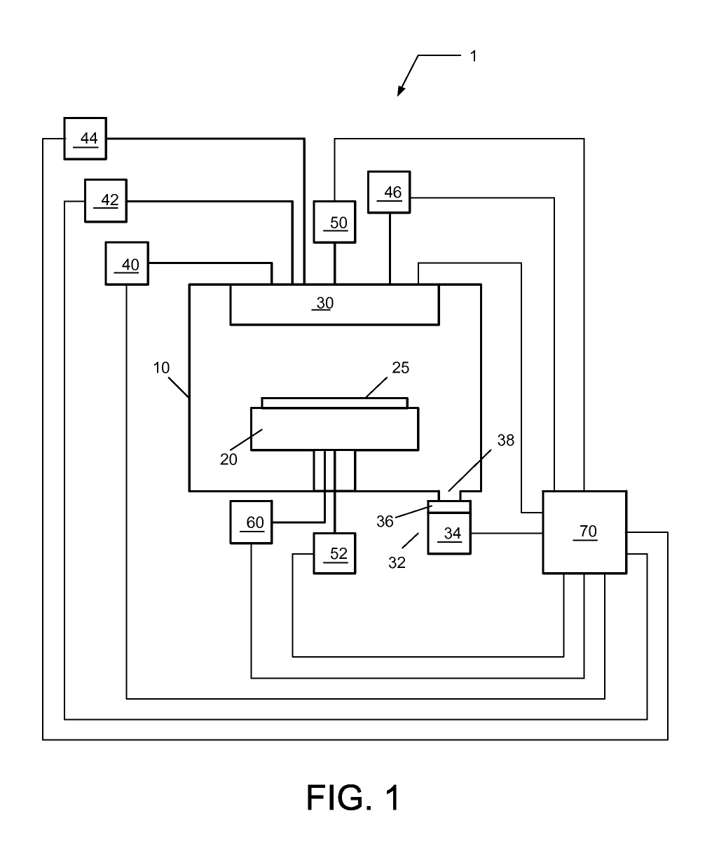

FIG. 1 depicts a schematic view of a processing system for forming a cobalt metal nitride barrier film in accordance with an embodiment of the invention. As those skilled in the art will readily recognize, the processing system 1 can be utilized to perform various deposition processes for depositing metal nitride films and cobalt films, including chemical vapor deposition (CVD), plasma-enhanced CVD (PECVD), atomic layer deposition (ALD), or plasma-enhanced ALD (PEALD). The processing system 1 includes a process chamber 10 having a substrate holder 20 configured to support a substrate 25 upon which the cobalt metal nitride barrier film is to be formed. The process chamber 10 further contains an upper assembly 30 coupled to a first process material supply system 40, a second process material supply system 42, a third process material supply system 44, and a purge gas supply system 46. Additionally, the processing system 1 includes a first power source 50 coupled to the process chamber 10 and configured to generate plasma in the process chamber 10, and a substrate temperature control system 60 coupled to substrate holder 20 and configured to elevate and control the temperature of the substrate 25.

The processing system 1 may be configured to process 200 mm substrates (wafers), 300 mm substrates, or larger-sized substrates. In fact, it is contemplated that the processing system 1 may be configured to process substrates, wafers, or flat panel displays regardless of their size, as would be appreciated by those skilled in the art. Therefore, while aspects of the invention will be described in connection with the processing of a semiconductor substrate, the invention is not limited solely thereto.

The first process material supply system 40 and the second process material supply system 42 are configured to simultaneously or sequentially introduce a first process material and a second process material to the process chamber 10. Sequential introduction of the first process material and the introduction of the second material can be cyclical, or it may be acyclical with variable time periods between introduction of the first and second process materials. The first process material can, for example, contain a metal precursor or metal nitride precursor selected from a Ta-containing precursor, a Ti-containing precursor, or a W-containing precursor. For instance, the metal precursor or metal nitride precursor can originate as a solid phase, a liquid phase, or a gaseous phase, and it may be delivered to process chamber 10 in a gaseous phase with or without the use of a carrier gas. The second process material can, for example, contain a reducing gas, a nitriding gas, or a combination thereof, and it may be delivered to process chamber 10 with or without the use of a carrier gas. The reducing gas can contain H₂, plasma excited H₂, or BH₃, or a combination of two or more thereof. The nitriding gas can contain NH₃, plasma excited NH₃, plasma-excited N₂, NH(CH₃)₂, N₂H₄, or N₂H₃CH₃, or a combination of two or more thereof. The third process material supply system 44 can be configured for introducing a third process material containing a cobalt precursor for depositing a cobalt film containing cobalt metal or a cobalt nitride on the substrate 25.

Additionally, the purge gas supply system 46 can be configured to introduce a purge gas to process chamber 10. For example, the introduction of purge gas may occur between introduction of the first process material and the second process material, following the introduction of the second process material, between the introduction of the second process material and the third process material, and following introduction of the third process material. The purge gas can comprise an inert gas, such as a noble gas (i.e., helium, neon, argon, xenon, krypton), N₂, or H₂.

Still referring to FIG. 1, the processing system 1 includes a plasma generation system configured to generate a plasma in the process chamber 10 during deposition of the cobalt metal nitride barrier film, for example during introduction of the second process material into the process chamber 10. The plasma generation system can include the first power source 50 coupled to the process chamber 10, and configured to couple power to gases in the process chamber 10. The first power source 50 may be a variable power source and may include a radio frequency (RF) generator and an impedance match network, and may further include an electrode through which RF power is coupled to the plasma in process chamber 10. The electrode can be formed in the upper assembly 30, and it can be configured to oppose the substrate holder 20. The impedance match network can be configured to optimize the transfer of RF power from the RF generator to the plasma by matching the output impedance of the match network with the input impedance of the process chamber 10, including the electrode, and plasma. For instance, the impedance match network serves to improve the transfer of RF power to plasma in the process chamber 10 by reducing the reflected power. Match network topologies (e.g. L-type, π-type, T-type, etc.) and automatic control methods are well known to those skilled in the art.

Alternatively, the first power source 50 may include a RF generator an impedance match network, and an antenna, such as an inductive coil, through which RF power is coupled to plasma in process chamber 10. The antenna can, for example, include a helical or solenoidal coil, such as in an inductively coupled plasma source or helicon source, or it can, for example, include a flat coil as in a transformer coupled plasma source.

Alternatively, the first power source 50 may include a microwave frequency generator, and may further include a microwave antenna and microwave window through which microwave power is coupled to plasma in process chamber 10. The coupling of microwave power can be accomplished using electron cyclotron resonance (ECR) technology, or it may be employed using surface wave plasma technology, such as a slotted plane antenna (SPA), as described in U.S. Pat. No. 5,024,716, the contents of which are herein incorporated by reference in its entirety.

According to one embodiment of the invention, the processing system 1 includes a substrate bias generation system configured to generate or assist in generating a plasma (through substrate holder biasing) during at least a portion of the deposition of the cobalt metal nitride barrier film. The substrate bias system can include a substrate power source 52 coupled to the process chamber 10, and configured to couple power to substrate 25. The substrate power source 52 may include a RF generator and an impedance match network, and may further include an electrode through which RF power is coupled to substrate 25. The electrode can be formed in substrate holder 20. For instance, substrate holder 20 can be electrically biased at a RF voltage via the transmission of RF power from a RF generator (not shown) through an impedance match network (not shown) to substrate holder 20. A typical frequency for the RF bias can range from about 0.1 MHz to about 100 MHz, and can be 13.56 MHz. RF bias systems for plasma processing are well known to those skilled in the art. Alternatively, RF power is applied to the substrate holder electrode at multiple frequencies. In one example, the substrate power source 52 may generate a plasma in the process chamber 10 through biasing of the substrate holder 20 while the upper assembly 30 is grounded.

Although the plasma generation system and the substrate bias system are illustrated in FIG. 1 as separate entities, they may indeed comprise one or more power sources coupled to substrate holder 20.

Still referring to FIG. 1, processing system 1 includes substrate temperature control system 60 coupled to the substrate holder 20 and configured to elevate and control the temperature of substrate 25. Substrate temperature control system 60 comprises temperature control elements, such as a cooling system including a re-circulating coolant flow that receives heat from substrate holder 20 and transfers heat to a heat exchanger system (not shown), or when heating, transfers heat from the heat exchanger system to the substrate holder 20. Additionally, the temperature control elements can include heating/cooling elements, such as resistive heating elements, or thermoelectric heaters/coolers, which can be included in the substrate holder 20, as well as the chamber wall of the process chamber 10 and any other component within the processing system 1.

In order to improve the thermal transfer between substrate 25 and substrate holder 20, the substrate holder 20 can include a mechanical clamping system, or an electrical clamping system, such as an electrostatic clamping system, to affix substrate 25 to an upper surface of substrate holder 20. Furthermore, substrate holder 20 can further include a substrate backside gas delivery system configured to introduce gas to the back-side of substrate 25 in order to improve the gas-gap thermal conductance between substrate 25 and substrate holder 20. Such a system can be utilized when temperature control of the substrate 25 is required at elevated or reduced temperatures. For example, the substrate backside gas system can comprise a two-zone gas distribution system, wherein the helium gas gap pressure can be independently varied between the center and the edge of substrate 25.

Furthermore, the process chamber 10 is further coupled to a pressure control system 32, including a vacuum pumping system 34 and a valve 36, through a duct 38, wherein the pressure control system 32 is configured to controllably evacuate the process chamber 10 to a pressure suitable for forming the thin film on substrate 25, and suitable for use of the first and second process materials. The vacuum pumping system 34 can include a turbo-molecular vacuum pump (TMP) or a cryogenic pump capable of a pumping speed up to about 5000 liters per second (and greater) and valve 36 can include a gate valve for throttling the chamber pressure. In conventional processing systems, a 300 to 5000 liter per second TMP is generally employed. Moreover, a device for monitoring chamber pressure (not shown) can be coupled to the process chamber 10. The pressure measuring device can, for example, be a capacitance manometer.

The processing system 1 includes a controller 70 that can be used to configure any number of processing elements of the processing system 1, and the controller 70 can collect, provide, process, store, and display data from processing elements. The controller 70 can comprise a number of applications for controlling one or more of the processing elements. For example, controller 70 can include a graphic user interface (GUI) component (not shown) that can provide easy to use interfaces that enable a user to monitor and/or control one or more processing elements. Alternatively, or in addition, controller 70 can be coupled to one or more additional controllers/computers (not shown), and controller 70 can obtain setup and/or configuration information from an additional controller/computer.

The controller 70 can comprise a microprocessor, memory, and a digital I/O port capable of generating control voltages sufficient to communicate and activate inputs of the processing elements of the processing system 1 as well as monitor outputs from the processing system 1. For example, a program stored in the memory may be utilized to activate the inputs to the aforementioned components of the processing system 1 according to a process recipe in order to perform an etching process, or a deposition process.

The controller 70 may be implemented as a general purpose computer system that performs a portion or all of the microprocessor based processing steps of embodiments of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 70, for driving a device or devices for implementing embodiments the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing embodiments of the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the processing system 1, or it may be remotely located relative to the processing system 1. For example, the controller 70 may exchange data with the processing system 1 using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the processing system 1 via a wireless connection.

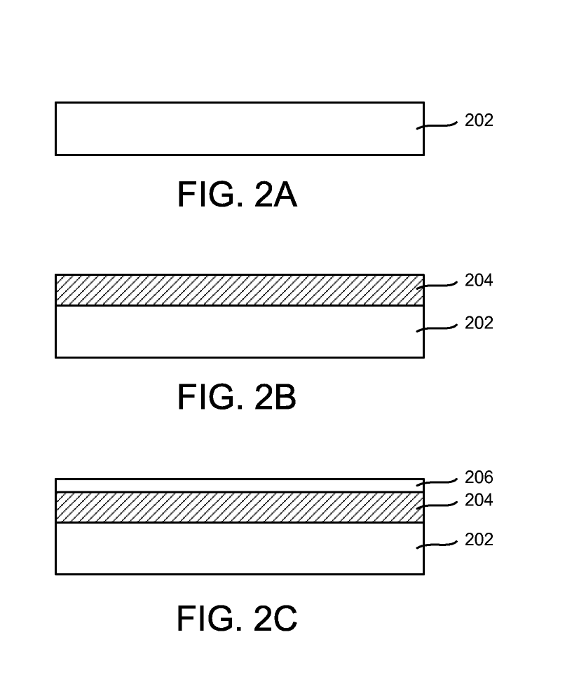

FIGS. 2-5 schematically show methods for forming multilayer structures containing a cobalt metal nitride barrier film according to embodiments of the invention.

FIG. 2A schematically shows a substrate 202 to be processed. The substrate 202 can, for example, be a silicon (Si) substrate, a dielectric material containing SiO₂, SiON, SiN, or a low dielectric constant (low-k) material having a dielectric constant less than that of SiO₂ (k˜3.9). Common low-k materials can contain simple or complex compounds of Si, O, N, C, H, or halogens, either as dense or porous materials. In other embodiments, the substrate 202 can be portion of an interconnect structure and can contain a metal, for example Cu, W, or Al, or a silicide, for example nickel silicide, cobalt silicide, or titanium silicide.

In FIG. 2B, a cobalt metal nitride barrier film 204 is formed on the substrate 202. The cobalt metal nitride barrier film can, for example, contain cobalt tantalum nitride, cobalt tantalum carbonitride, cobalt titanium nitride, cobalt titanium carbonitride, cobalt tungsten nitride, or cobalt tungsten carbonitride, or a combination thereof. A thickness of the cobalt metal nitride barrier film 204 can, for example, be between about 1 nm and about 10 nm, or between about 2 nm and about 5 nm, for example about 4 nm.

According to embodiments of the invention, the cobalt metal nitride barrier film 204 may be formed using a metal precursor or a metal nitride precursor, a cobalt source, and a reducing gas and/or a nitriding gas in CVD, PECVD, ALD, or PEALD, or a combination thereof. In one example, a metal nitride precursor can contain tantalum and nitrogen but a separate nitrogen precursor (e.g., NH₃ or plasma-excited N₂) may be added as an additional source of nitrogen.

In ALD and PEALD processing, a substrate temperature is selected below the thermal decomposition temperature to sequentially adsorb a metal precursor or metal nitride precursor, and a cobalt precursor on the substrate surface in a self-limiting manner, where the adsorption stops when the thickness of the adsorbed precursor corresponds to about one atomic layer or less. The thermal decomposition temperature of the selected metal precursor or metal nitride and cobalt precursor may be determined by experimentation or obtained from the literature. In CVD processing, a substrate temperature is selected that is above the thermal decomposition temperature of the precursors to react and deposit a film on the surface in a non-limiting manner, where the deposition stops when the precursor exposure ends.

A wide variety of Ta-containing precursors may be utilized for depositing tantalum nitride (or carbonitride) layers for a cobalt tantalum nitride barrier film 204. The Ta-containing precursors may be selected from tantalum nitride precursors and tantalum precursors. Tantalum nitride (or carbonitride) precursor can contain both tantalum and nitrogen in the same molecule but a separate nitrogen precursor (e.g., NH₃ or plasma-excited N₂) may be added as an additional source of nitrogen. Representative examples of tantalum nitride precursor containing “Ta—N” intra-molecular bonds include Ta(NMe₂)₃(NCMe₂Et) (TAIMATA), Ta(NEt₂)₅ (PDEAT), Ta(NMe₂)₅ (PDMAT), Ta(NEtMe)₅ (PEMAT), (tBuN)Ta(NMe₂)₃ (TBTDMT), (tBuN)Ta(NEt₂)₃ (TBTDET), (tBuN)Ta(NEtMe)₃ (TBTEMT), and (iPrN)Ta(NEt₂)₃ (IPTDET). Tantalum precursors can include TaF₅ and TaCl₅ and precursors containing “Ta—C” intra-molecular bonds include, for example, Ta(η⁵-C₅H₅)₂H₃, Ta(CH₂)(CH₃)(η⁵-C₅H₅)₂, Ta(η³-C₃H₅) (η⁵-C₅H₅)₂, Ta(CH₃)₃(η⁵-C₅H₅)₂, Ta(CH₃)₄(η⁵-C₅(CH₃)₅), or Ta(η⁵-C₅(CH₃)₅)₂H₃.

The Ti-containing precursors may be selected from titanium nitride precursors and titanium precursors. Titanium nitride (or carbonitride) precursors can contain both titanium and nitrogen in the same molecule but a separate nitrogen precursor (e.g., NH₃ or plasma-excited N₂) may be added as an additional source of nitrogen. Representative examples of titanium nitride precursor having “Ti—N” intra-molecular bonds include Ti(NEt₂)₄ (TDEAT), Ti(NMeEt)₄ (TEMAT), Ti(NMe₂)₄ (TDMAT). Titanium precursors can include TiF₅ and TiCl₅ and precursors containing “Ti—C” intra-molecular bonds include, for example, Ti(COCH₃)(η⁵-C₅H₅)₂Cl, Ti(η⁵-C₅H₅)Cl₂, Ti(η⁵-C₅H₅)Cl₃, Ti(η⁵-C₅H₅)₂Cl₂, Ti(η⁵-C₅(CH₃)₅)Cl₃, Ti(CH₃)(η⁵-C₅H₅)₂Cl, Ti(η⁵C₉H₇)₂Cl₂, Ti((η⁵-C₅(CH₃)₅)₂Cl, Ti((η⁵-C₅(CH₃)₅)₂Cl₂, Ti(η⁵-C₅H₅)₂(μ-Cl)₂, Ti(η⁵-C⁵H₅)₂(CO)₂, Ti(CH₃)₃(η⁵-C₅H₅), Ti(CH₃)₂(η⁵-C₅H₅)₂, Ti(CH₃)₄, Ti(η⁵-C₅H₅)(η⁷-C₇H₇), Ti(η⁵-C₅H₅)(η⁸-C₈H₈), Ti(C₅H₅)₂(η⁵-C₅H₅)₂, Ti((C₅H₅)₂)₂(η-H)₂, Ti(η⁵-C₅(CH₃)₅)₂, Ti(η⁵-C₅(CH₃)₅)₂(H)₂, and Ti(CH₃)₂(η⁵(CH₃)₅)₂.

Examples of W-containing precursors include WF₆, W(CO)₆, and bis(tert-butylimido)bis(dimethylamido)tungsten ((tBuN)₂(Me₂N)₂W).

Embodiments of the invention may utilize a wide variety of cobalt precursors for depositing cobalt. Examples include Co₂(CO)₈, CoCp(CO)₂, Co(CO)₃(NO), dicobalt hexacarbonyl t-butylacetylene (Co(CO)₆(HCCtBu), Co(acac)₂, Co(Cp)₂, bis(pentamethylcyclopentadienyl)cobalt(II) (Co(Me₅Cp)₂), bis(ethylcyclopentadienyl)cobalt(II) (Co(EtCp)₂), cobalt(II) hexafluoroacetylacetonate hydrate, cobalt tris(2,2,6,6-tetramethyl-3,5-heptanedionate), cobalt(III) acetylacetonate, bis(N,N′-diisopropylacetamidinato)cobalt, and tricarbonyl allyl cobalt.

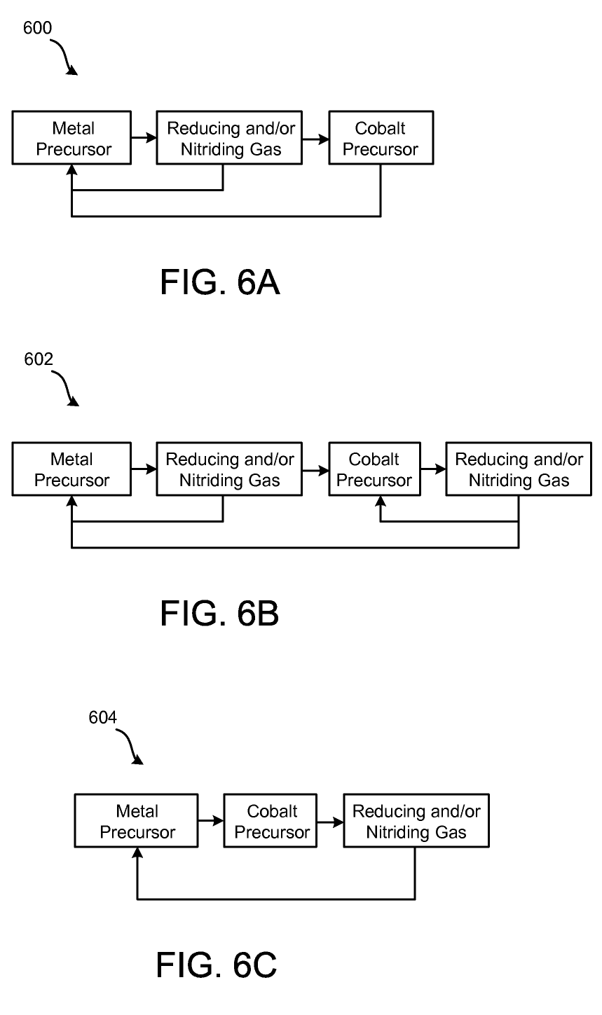

FIGS. 6A-6C show process flow diagrams for forming a cobalt metal barrier film according to embodiments of the invention.

FIG. 6A schematically shows formation of cobalt metal nitride barrier film 204 according to one embodiment of the invention. The process 600 includes depositing metal nitride (or carbonitride) layer(s) on a substrate by sequential and alternating exposures of a metal precursor (e.g., Ta-, Ti-, or W-containing precursor) and a reducing gas (e.g., plasma-excited H₂) and/or a nitriding gas (e.g., NH₃, plasma-excited NH₃, or plasma-excited N₂) with purge/evacuation steps between the alternating exposures. The alternating exposures of the metal precursor and the reducing and/or nitriding gas may be repeated a first number of times. The first number of times can, for example, be between 1 and 100, between 1 and 20, or between 1 and 5.

Next, the substrate is exposed to a cobalt precursor to deposit cobalt on the metal nitride layer(s). Next, the metal nitride deposition and the cobalt deposition may be repeated a second number of times until the cobalt metal nitride barrier film has a desired thickness. A thickness of the cobalt metal nitride barrier film 204 can, for example, be between about 1 nm and about 10 nm, or between about 2 nm and about 5 nm, for example about 4 nm. The second number of times can, for example, be between 1 and 100, between 1 and 20, or between 1 and 5. In one example, the process 600 may end with an exposure to the reducing and/or nitriding gas. In another example, the process may end with an exposure to the cobalt precursor.

In one embodiment, the first number of times may be used to control the relative amounts of the metal nitride and cobalt in the deposited cobalt metal nitride barrier film. In one example, the first number of times may be varied following each cobalt precursor exposure to vary the cobalt content throughout a thickness of the cobalt metal nitride barrier film 204, thereby forming a graded cobalt metal nitride barrier film 204 with increasing or decreasing cobalt content throughout the film 204.

During deposition of the cobalt metal nitride barrier film 204, the intermixing ratios of metal nitride and the cobalt may be affected by controlling the thickness of the alternating metal nitride and cobalt layers. The deposited cobalt metal nitride barrier film may be post-annealed in order to further intermix the metal nitride and cobalt layers to form an amorphous cobalt metal nitride barrier film 204 with desired electrical and materials properties. In one example, the cobalt metal nitride barrier film 204 may be annealed at a temperature between 200° C. and 500° C.

In one example, a plurality of tantalum nitride layers may be deposited by PEALD using alternating exposures of TAIMATA and plasma-excited H₂. The tantalum nitride layers may contain similar amounts of N and C, for example as TaC_{0.5}N_{0.5}. The TAIMATA exposures may utilize a substrate temperature below the TAIMATA thermal decomposition temperature of about 300° C., for example between about 150° C. and less than 300° C. Exemplary TAIMATA exposure times can be between 0.1 and 10 seconds, and exemplary plasma-excited H₂ exposure times can be between 1 and 30 seconds.

FIG. 6B schematically shows formation of a cobalt metal nitride barrier film 204 according to another embodiment of the invention. The process 602 is similar to the process 600 described above for FIG. 6A but further includes, following the exposure to a cobalt precursor, exposing the substrate to a reducing gas and/or a nitriding gas, with purge/evacuation steps between the alternating exposures. The reducing gas can, for example, include H₂, plasma excited H₂, or BH₃, or a combination of two or more thereof, and the nitriding gas can, for example, include NH₃, plasma excited NH₃, plasma-excited N₂, NH(CH₃)₂, N₂H₄, or N₂H₃CH₃NH₃, or a combination of two or more thereof. The alternating exposures of the cobalt precursor and the reducing and/or nitriding gas may be repeated a third number of times and the process 602 repeated a fourth number of times. The third and fourth number of times can, for example, be between 1 and 100, between 1 and 20, or between 1 and 5. The alternating exposures of the cobalt precursor and the reducing and/or nitriding gas can deposit a cobalt film containing cobalt metal or a cobalt nitride.

In one embodiment, the third and fourth number of times may be used to control the relative amounts of the metal nitride and cobalt in the deposited cobalt metal nitride barrier film 204. In one example, the third and/or the fourth number of times may be varied during the process 602 to vary the cobalt content throughout a thickness of the cobalt metal nitride barrier film 204, thereby forming a graded cobalt metal nitride barrier film 204 with increasing or decreasing cobalt content throughout the film 204.

FIG. 6C schematically shows formation of a cobalt metal nitride barrier film 204 according to one embodiment of the invention. The process 604 includes alternating exposures of a metal precursor (e.g., Ta-, Ti-, or W-containing precursor) and a reducing gas (e.g., plasma-excited H₂) and/or a nitriding gas (e.g., NH₃, plasma-excited NH₃, or plasma-excited N₂), with purge/evacuation steps between the alternating exposures. The alternating exposures in the process 606 may be repeated a number of times. The number of times can, for example, be between 1 and 100, between 1 and 20, or between 1 and 5. The number of times may be used to control relative amounts of the metal nitride and the cobalt in the deposited cobalt metal nitride film 204.

In one example, the cobalt metal nitride barrier film 204 may be deposited by PEALD using the process 604, including alternating exposures of TAIMATA, a cobalt source, and plasma-excited H₂. The TAIMATA exposures may utilize a substrate temperature below the thermal decomposition temperature of about 300° C., for example between about 150° C. and less than 300° C. Exemplary TAIMATA exposure times can be between 0.1 and 10 seconds, and exemplary plasma-excited H₂ exposure times can be between 1 and 30 seconds.

According to one embodiment of the invention, the cobalt metal nitride film 204 may be deposited using CVD by simultaneously exposing the substrate to a metal nitride precursor or a metal precursor, a cobalt precursor, and a reducing gas, nitriding gas, or a combination thereof.

Referring now to FIG. 2C, following deposition of the cobalt metal nitride barrier film 204, bulk Cu metal 206 may be formed on the cobalt metal nitride barrier film 204. In one example, formation of the bulk Cu metal 206 may include plating bulk Cu metal directly on the cobalt metal nitride barrier film 204. Bulk Cu metal deposition processes are well known by one of ordinary skill in the art of circuit fabrication and can, for example, include an electrochemical plating process or an electroless plating process. Other bulk Cu metal deposition processes are also available, for example Cu sputtering processes.

In another example, formation of the bulk Cu metal 206 may include depositing a Cu seed layer (not shown) on the cobalt metal nitride barrier film 204, and subsequently plating bulk Cu metal on the Cu seed layer. The Cu seed layer can provide a Cu growth surface for the Cu plating process. A thickness of the Cu seed layer can, for example, be between about 0.5 nm and about 20 nm, or between about 1 nm and about 3 nm, for example about 2 nm. The Cu seed layer may be deposited by sputtering methods, for example by ionized physical vapor deposition (IPVD). An exemplary IPVD system is described in U.S. Pat. No. 6,287,435. In one example, the Cu seed layer 130 may be deposited using a capacitively coupled plasma (CCP) system where a Cu sputtering target forms an upper electrode and a substrate holder upon which the substrate is positioned forms a lower electrode. However, other types of plasma systems can be used.

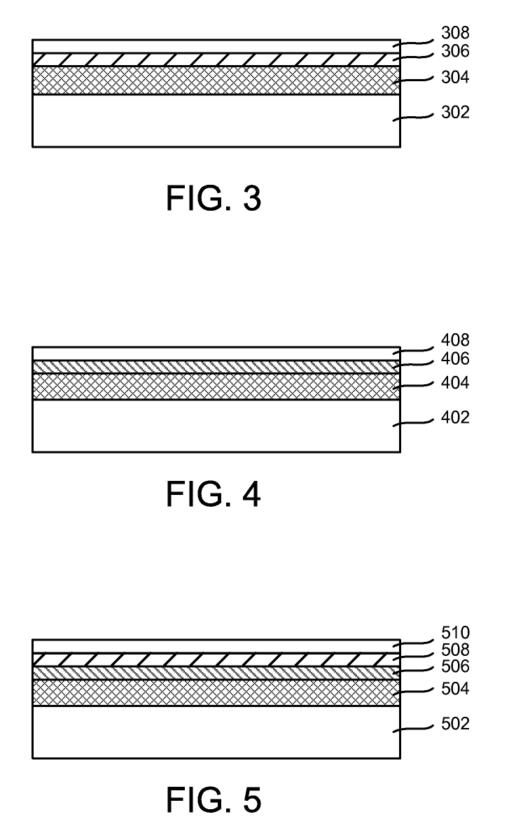

FIG. 3 schematically shows a multilayer structure containing a cobalt metal nitride barrier film according to another embodiment of the invention. The multilayer structure depicted in FIG. 3 is similar to the multilayer structure depicted in FIG. 2C and contains a substrate 302, a cobalt metal nitride barrier film 304 deposited on the substrate 302, a ruthenium (Ru) metal film 306 deposited on the cobalt metal nitride barrier film 304, and bulk Cu metal 308 formed on the Ru metal film 306. The cobalt metal nitride barrier film 304 and the bulk Cu metal 308 may be formed as described above for the cobalt metal nitride barrier film 204 and the bulk Cu metal 206 in FIGS. 2A-2C.

In one example, the Ru metal film 306 may be deposited using a Ru CVD system and method described U.S. Pat. No. 7,270,848, entitled METHOD AND DEPOSITION SYSTEM FOR INCREASING DEPOSITION RATES OF METAL LAYERS FROM METAL-CARBONYL PRECURSORS, the entire content of which is herein incorporated by reference. In other examples, the Ru metal film 306 may be deposited using ruthenium metalorganic precursors, for example (2,4-dimethylpentadienyl)(ethylcyclopentadienyl)ruthenium (Ru(DMPD)(EtCp)), bis(2,4-dimethylpentadienyl)ruthenium (Ru(DMPD)₂), 4-dimethylpentadienyl)(methylcyclopentadienyl)ruthenium (Ru(DMPD)(MeCp)), and bis(ethylcyclopentadienyl)ruthenium (Ru(EtCp)₂), as well as combinations of these and other precursors. In another example, the Ru metal film 306 may be deposited by Ru ALD. Still other examples for depositing the Ru metal film 306 include sputtering methods using a solid Ru metal target.

FIG. 4 schematically shows a multilayer structure containing a cobalt metal nitride barrier film according to yet another embodiment of the invention. The multilayer structure depicted in FIG. 4 is similar to the multilayer structure depicted in FIG. 2C and contains a substrate 402, a cobalt metal nitride barrier film 404 on the substrate 402, a Co film 406 deposited on the cobalt metal nitride film 404, and bulk Cu metal 408 formed on the cobalt film 406. The cobalt metal nitride barrier film 404 and the bulk Cu metal 408 may be formed as described above for the cobalt metal nitride barrier film 204 and the bulk Cu metal 206 in FIGS. 2A-2C. The Co film 406 may contain Co metal, Co nitride, or a combination thereof. The Co film 406 may be deposited by CVD, PECVD, ALD, PEALD, or a combination thereof. In one example, the Co film 406 may be deposited as described in FIG. 6B.

FIG. 5 schematically shows a multilayer structure containing a cobalt metal nitride barrier film according to yet another embodiment of the invention. The multilayer structure depicted in FIG. 5 is similar to the multilayer structures depicted in FIGS. 3 and 4 and contains a substrate 502, a cobalt metal nitride barrier film 504 deposited on the substrate 502, a Co film 506 deposited on the cobalt metal nitride barrier film 504, a Ru metal film 508 deposited on the Co film 506, and bulk Cu metal 510 formed on the Ru metal film 508. The cobalt metal nitride barrier film 504 and the bulk Cu metal 510 may be formed as described above for the cobalt metal nitride barrier film 204 and the bulk Cu metal 206 in FIGS. 2A-2C. The Co film 406 may contain Co metal, Co nitride, or a combination thereof. The Co film 406 may be deposited by CVD, PECVD, ALD, PEALD, or a combination thereof. In one example, the Co film 406 may be deposited as described in FIG. 6B. The Ru metal film 508 may be deposited as described above for the Ru metal film 306 in FIG. 3.

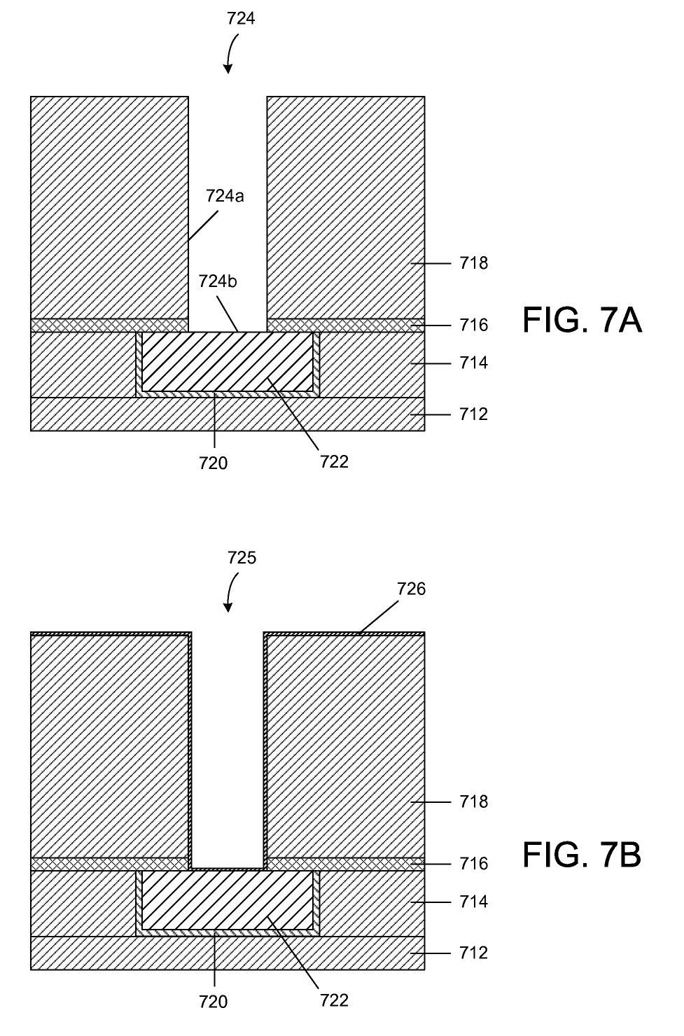

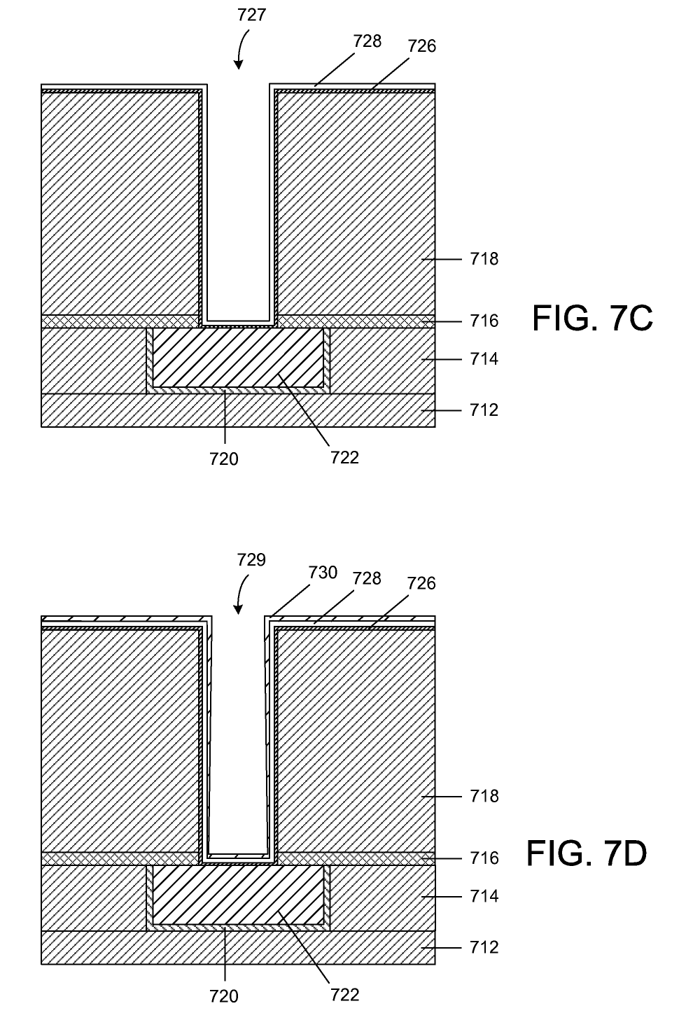

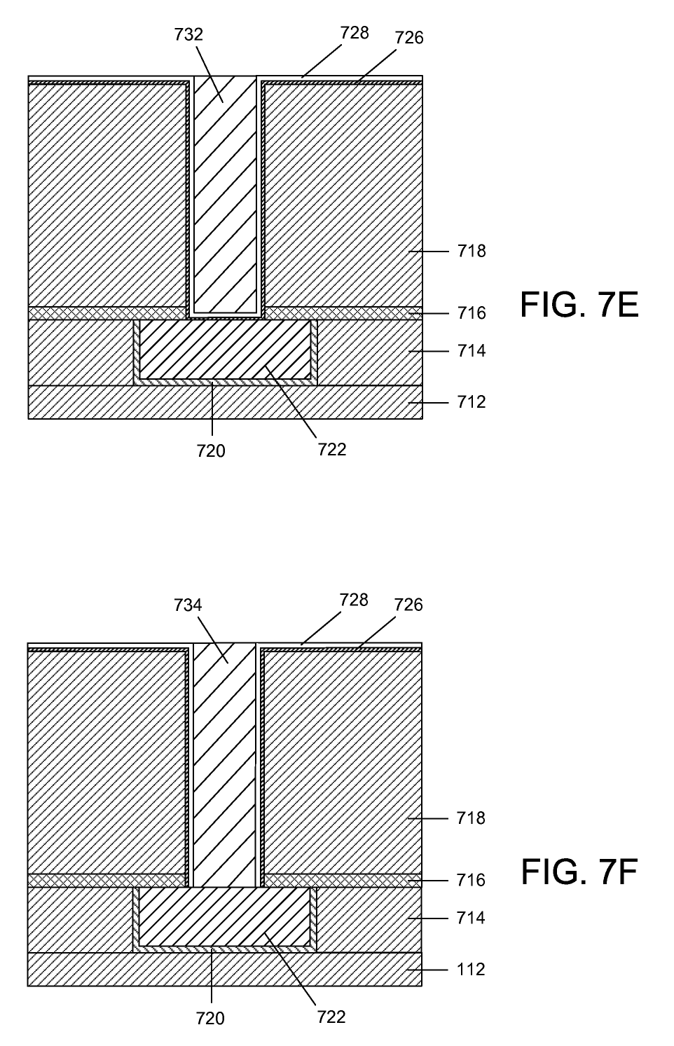

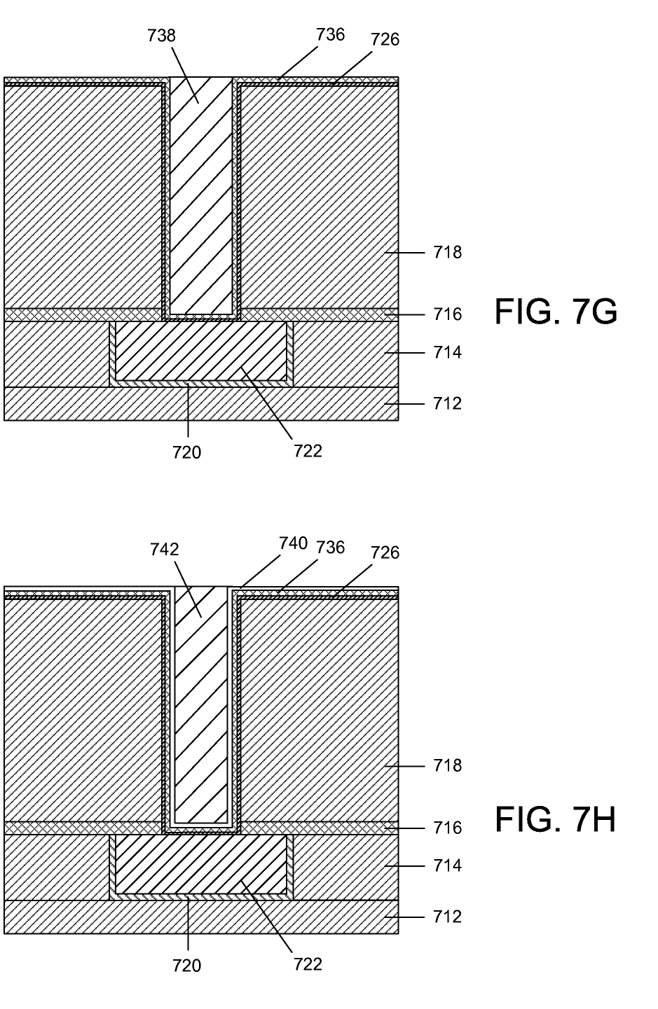

FIGS. 7A-7H schematically show methods for forming a semiconductor device containing a cobalt metal nitride barrier film according to embodiments of the invention.

FIG. 7A schematically shows a cross-sectional view of a partially formed semiconductor device having a recessed feature 724 formed in dielectric material 718 over a conductive interconnect structure 722. The recessed feature 724 includes sidewall and bottom surfaces 724a and 724b, respectively. The semiconductor device further contains dielectric layers 712 and 714, a barrier layer 720 surrounding the conductive interconnect structure 722, and an etch stop layer 716. The conductive interconnect structure 722 can, for example, contain Cu or W.

According to an embodiment of the invention, the recessed feature 724 can be a via having an aspect ratio (depth/width) greater than or equal to about 2:1, for example 3:1, 4:1, 5:1, 6:1, 12:1, 15:1, or higher. The via can have widths of about 200 nm or less, for example 150 nm, 90 nm, 64 nm, 45 nm, 32 nm, 20 nm, or lower. However, embodiments of the invention are not limited to these aspect ratios or via widths, as other aspect ratios and via widths may be utilized.

In FIG. 7B, a cobalt metal nitride barrier film 726 is formed over the semiconductor device, including on the sidewall and bottom surfaces 724a and 724b of the recessed feature 724 to form recessed feature 725. A thickness of the cobalt metal nitride barrier film 726 can, for example, be between about 1 nm and about 10 nm, or between about 2 nm and about 5 nm, for example about 4 nm.

In FIG. 7C, a Ru metal film 728 is deposited on the cobalt metal nitride barrier film 726 to form recessed feature 727. A thickness of the Ru metal film 728 can, for example, be less than about 10 nm, for example about 5 nm, about 4 nm, about 3 nm, about 2 nm, or about 1 nm. The deposited Ru metal film 728 may be heat treated at a temperature between about 100° C. and about 400° C. During the heat treating, the Ru metal film 728 may be exposed to an inert gas, H₂, or a combination of an inert gas and H₂. The inert gas can, for example, be selected from a noble gas such as Ar and N₂. An exemplary combination includes 10:1 H₂:Ar. Exemplary heat treatments of the Ru metal film 728 include gas pressure of 3 Torr and process time of 30 minutes, but embodiments of the invention are not limited by these processing conditions as other heat treating conditions may be utilized. For example, the gas pressure can be between about 1 Torr and about 760 Torr, or between about 10 Torr and about 100 Torr.

In FIG. 7D, a Cu seed layer 730 is deposited over the semiconductor device to form recessed feature 729. The Cu seed layer 730 provides a Cu growth surface for a subsequent Cu plating process. A thickness of the Cu seed layer 730 can, for example, be between about 0.5 nm and about 20 nm, or between about 1 nm and about 3 nm, for example about 2 nm.

In FIG. 7E, the recessed feature 729 is filled with bulk Cu metal 732 and excess Cu metal removed by a chemical mechanical polishing (CMP) process. Although not shown in FIG. 7E, the CMP process may at least partially remove the Ru metal film 728 and the cobalt metal nitride barrier film 726 from the field area of the interconnect structure. According to another embodiment, deposition of the Cu seed layer 730 may be omitted and the bulk Cu metal 732 directly plated onto the Ru metal film 728.

According to another embodiment of the invention, the Ru metal film 728 and the cobalt metal nitride barrier film 726 at the bottom of the recessed feature 727 depicted in FIG. 7C may be at least partially removed by a sputter removal process prior to deposition of the Cu seed layer 730, in order to reduce the resistivity between bulk Cu metal filling the recessed feature and the conductive interconnect structure 722. FIG. 7F shows an interconnect structure where the Ru metal film 728 and the cobalt metal nitride barrier film 726 have been completely removed from the bottom of the recessed feature 727 prior to deposition of the Cu seed layer 730 and the bulk Cu metal 734, thereby directly contacting the bulk Cu metal 734 and the conductive interconnect structure 722. This reduces the resistivity of the interconnect structure in FIG. 7F compared to that of the interconnect structure depicted in FIG. 7E. Although not shown in FIG. 7F, removal of the Ru metal film 728 and the cobalt metal nitride barrier film 726 from the bottom of the recessed feature 724 may at least partially remove the Ru metal film 728 and the cobalt metal nitride barrier film 726 from other surfaces of the interconnect structure, such as the field area and sidewalls of the recessed feature 724. According to another embodiment, the cobalt metal nitride barrier film 726 may be removed from the bottom of the recessed feature 725 in FIG. 7B prior to deposition of the Ru metal film 728.

FIG. 7G shows an interconnect structure according to one embodiment of the invention. The interconnect structure depicted in FIG. 7G is similar to the interconnect structure depicted in FIG. 7E but the Ru metal film 728 has been replaced by a Co film 736 and bulk Cu metal 738 formed on the Co film 736. According to another embodiment, the cobalt metal nitride barrier film 726 and the Co film 736 may be removed from the bottom of the recessed feature prior to formation of the bulk Cu metal 738. According to another embodiment, the cobalt metal nitride barrier film 726 may be removed from the bottom of the recessed feature prior to deposition of the Co film 736.

FIG. 7H shows an interconnect structure according to another embodiment of the invention. The interconnect structure depicted in FIG. 7G is similar to the interconnect structures depicted in FIG. 7G but contains a Ru metal film 740 on the Co film 736 and bulk Cu metal 742 formed on the Ru metal film 740. According to another embodiment, the cobalt metal nitride barrier film 726 may be removed from the bottom of the recessed feature prior to deposition of the Co film 736 and the Ru metal film 740. According to another embodiment, the cobalt metal nitride barrier film 726 and the Co film 736 may be removed from the bottom of the recessed feature prior to deposition of the Ru film 740 and formation of the Ru metal film 740. According to another embodiment, the cobalt metal nitride barrier film 726, the Co film 736, and the Ru metal film 740, may be removed from the bottom of the recessed feature prior to the formation of the bulk Cu metal 742.

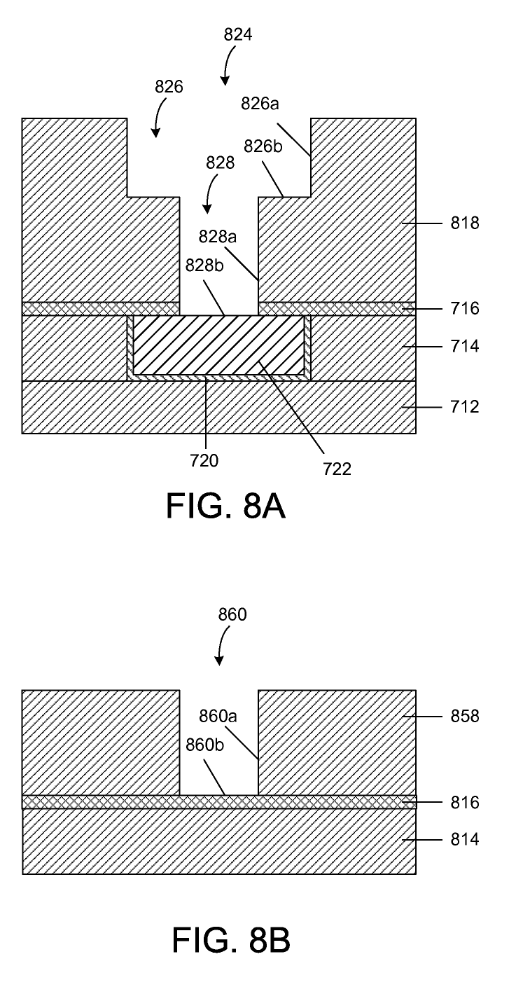

An exemplary recessed feature 724 was illustrated and described above in FIG. 7A, but embodiments of the invention may be applied to other types of recessed features found in integrated circuit design. FIGS. 8A and 8B show additional semiconductor device structures that may utilize a cobalt metal nitride barrier film according to embodiments of the invention. As will be appreciated by one of ordinary skill in the art, embodiments of the invention describing formation of a cobalt metal nitride barrier film and subsequent metallization steps can be readily applied to the semiconductor device structures depicted in FIGS. 8A and 8B.

FIG. 8A schematically shows a cross-sectional view of a semiconductor device containing a dual damascene interconnect structure. Dual damascene interconnects are well known by one of ordinary skill in the art of integrated circuit fabrication. The semiconductor device depicted in FIG. 8A is similar to the semiconductor device depicted in FIG. 7A but contains a dual damascene recessed feature 824 formed over conductive interconnect structure 722. The dual damascene recessed feature 824 contains a via 828 having sidewall and bottom surfaces 828a and 828b, respectively, and a trench 826 formed in dielectric material 818, where the trench 826 contains sidewall and bottom surfaces 826a and 826b, respectively. The trench 826 may be used for an upper conductive interconnect structure and the via 828 connects the trench 826 to the conductive interconnect structure 722. The semiconductor device further contains dielectric layers 712 and 714, barrier layer 720 surrounding the conductive interconnect structure 722, and etch stop layer 716. In accordance with embodiments of the invention, a cobalt metal nitride barrier film may be deposited on the sidewall and bottom surfaces of the trench 826 and via 828.

FIG. 8B schematically shows a cross-sectional view of a semiconductor device according to one embodiment of the invention. The semiconductor device contains a recessed feature (e.g., a trench) 860 within dielectric material 858. The recessed feature 860 includes sidewall and bottom surfaces 860a and 860b, respectively. The semiconductor device further contains dielectric layer 814 and etch stop layer 816. In accordance with embodiments of the invention, cobalt metal nitride barrier film may be deposited on the sidewall 860a and on the bottom surface 860b in contact with the etch stop layer 816.

A plurality of embodiments for formation of a cobalt metal nitride barrier film on a substrate and semiconductor devices containing a cobalt metal nitride barrier film have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a first film “on” a second film is directly on and in immediate contact with the second film unless such is specifically stated; there may be a third film or other structure between the first film and the second film on the first film.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of processing a substrate, the method comprising:
providing the substrate in a process chamber; and
forming a cobalt metal nitride barrier film on the substrate by:
depositing a plurality of metal nitride layers, and
depositing a cobalt layer containing cobalt metal or cobalt nitride between each of the plurality of metal nitride layers.

2. The method of claim 1, further comprising:
depositing a cobalt film containing cobalt metal or cobalt nitride on the cobalt metal nitride barrier film.

3. The method of claim 1, wherein depositing the plurality of metal nitride layers and depositing the cobalt layer is performed by ALD, PEALD, CVD, or PECVD, or a combination thereof.

4. The method of claim 1, wherein depositing the plurality of metal nitride layers comprises:
a) exposing the substrate to a metal precursor or a metal nitride precursor;
b) purging the process chamber;
c) exposing the substrate to a reducing gas, nitriding gas, or a combination thereof;
d) purging the process chamber; and
e) repeating steps a)-d).

5. The method of claim 1, wherein the forming comprises:
a) exposing the substrate to a metal precursor or a metal nitride precursor;
b) purging the process chamber;
c) exposing the substrate to a reducing gas, nitriding gas, or a combination thereof;
c) purging the process chamber; and
d) repeating steps a)-c);
e) exposing the substrate to a cobalt precursor; and
f) repeating steps a)-e) until the cobalt metal nitride barrier film has a desired thickness.

6. The method of claim 1, wherein the forming comprises:
a) exposing the substrate to a metal precursor or a metal nitride precursor;
b) purging the process chamber;
c) exposing the substrate to a cobalt precursor;
d) purging the process chamber;
e) exposing the substrate to a reducing gas, nitriding gas, or a combination thereof;
f) purging the process chamber; and
g) repeating steps a)-f) until the cobalt metal nitride barrier film has a desired thickness.

7. The method of claim 1, wherein the cobalt metal nitride barrier film has an amorphous structure with the cobalt at least substantially intermixed with the plurality of metal nitride layers.

8. The method of claim 1, wherein an amount of cobalt is gradually varied through a thickness of the cobalt metal nitride barrier film.

9. The method of claim 1, wherein the cobalt metal nitride barrier film comprises at least 5 atomic percent cobalt.

10. The method of claim 1, wherein the plurality of metal nitride layers comprise Ta, Ti, or W, or a combination thereof.

11. The method of claim 10, wherein depositing the plurality of metal nitride layers utilizes a metal nitride precursor comprising
Ta(NMe₂)₃(NCMe₂Et), Ta(NEt₂)₅, Ta(NMe₂)₅, Ta(NEtMe)₅, (tBuN)Ta(NMe₂)₃, (tBuN)Ta(NEt₂)₃, (tBuN)Ta(NEtMe)₃, (iPrN)Ta(NEt₂)₃, Ti(NEt₂)₄ (TDEAT), Ti(NMeEt)₄ (TEMAT), Ti(NMe₂)₄ (TDMAT), or tBuN)₂(Me₂N)₂W, or a metal precursor comprising Ta(η⁵-C₅H₅)₂H₃, Ta(CH₂)(CH₃)(η⁵-C₅H₅)₂, Ta(η³-C₃H₅) (η⁵-C₅H₅)₂, Ta(CH₃)₃(η⁵-C₅H₅)₂, Ta(CH₃)₄(η⁵-C₅(CH₃)₅), Ta(η⁵-C₅(CH₃)₅)₂H₃, Ti(COCH₃)(η⁵-C₅H₅)₂Cl, Ti(η⁵-C₅H₅)Cl₂, Ti(η⁵-C₅H₅)Cl₃, Ti(η⁵-C₅H₅)₂Cl₂, Ti(η⁵-C₅(CH₃)₅)Cl₃, Ti(CH₃)(η⁵-C₅H₅)₂Cl, Ti(η⁵-C₉H₇)₂Cl₂, Ti((η⁵-C₅(CH₃)₅)₂Cl , Ti((η⁵-C₅(CH₃)₅)₂Cl₂, Ti(η⁵-C₅H₅)₂(μ-Cl)₂, Ti(η⁵-C₅H₅)₂(CO)₂, Ti(CH₃)₃(η⁵-C₅H₅), Ti(CH₃)₂(η⁵-C₅H₅)₂, Ti(CH₃)₄, Ti(η⁵-C₅H₅)(θ⁷-C₇H₇), Ti(θ⁵-C₅H₅)(η⁸-C₈H₈), Ti(C₅H₅)₂(η⁵-C₅H₅)₂, Ti((C₅H₅)₂)₂(η-H)₂, Ti(η⁵-C₅(CH₃)₅)₂, Ti(η⁵-C₅(CH₃)₅)₂(H)₂, Ti(CH₃)₂(η⁵-C₅(CH₃)₅)₂, WF₆, or W(CO)₆, a reducing gas or a nitriding gas, or both a reducing gas and a nitriding gas, wherein the reducing gas comprises H₂, plasma-excited H₂, or BH₃, or a combination of two or more thereof, and the nitriding gas comprises NH₃, plasma excited NH₃, plasma-excited N₂, NH(CH₃)₂, N₂H₄, or N₂H₃CH₃, or a combination of two or more thereof.

12. The method of claim 1, wherein depositing the cobalt layer comprises exposing the substrate to cobalt precursor comprising Co₂(CO)₈, CoCp(CO)₂, Co(CO)₃(NO), Co₂(CO)₆(HCCtBu), Co(acac)₂, Co(Cp)₂, Co(Me₅Cp)₂), Co(EtCp)₂, cobalt(II) hexafluoroacetylacetonate hydrate, cobalt tris(2,2,6,6-tetramethyl-3,5-heptanedionate), cobalt(III) acetylacetonate, bis(N,N′-diisopropylacetamidinato)cobalt, or tricarbonyl allyl cobalt, or a combination of two or more thereof.

13. The method of claim 1, further comprising:
post-annealing the cobalt metal nitride barrier film at a temperature between 200° C. and 500° C.

14. A method of processing a substrate, the method comprising:
providing the substrate in a process chamber; and
forming a cobalt metal nitride barrier film on the substrate by simultaneously exposing the substrate to a metal nitride precursor or a metal precursor, a cobalt precursor, and a reducing gas, nitriding gas, or a combination thereof.

15. The method of claim 14, further comprising:
depositing cobalt film containing cobalt metal or cobalt nitride on the cobalt metal nitride barrier film.

16. The method of claim 14, wherein the cobalt metal nitride barrier film has an amorphous structure.

17. The method of claim 14, wherein an amount of cobalt is gradually varied through a thickness of the cobalt metal nitride barrier film.

18. The method of claim 14, wherein the cobalt metal nitride barrier film comprises at least 5 atomic percent cobalt.

19. The method of claim 14, wherein the cobalt metal nitride barrier film comprises Ta, Ti, or W, or a combination thereof.

20. The method of claim 14, wherein the metal nitride precursor comprises Ta(NMe₂)₃(NCMe₂Et), Ta(NEt₂)₅, Ta(NMe₂)₅, Ta(NEtMe)₅, (tBuN)Ta(NMe₂)₃, (tBuN)Ta(NEt₂)₃, (tBuN)Ta(NEtMe)₃, (iPrN)Ta(NEt₂)₃, Ti(NEt₂)₄ (TDEAT), Ti(NMeEt)₄ (TEMAT), Ti(NMe₂)₄ (TDMAT), or tBuN)₂(Me₂N)₂W, the metal precursor comprises Ta(η⁵-C₅H₅)₂H₃, Ta(CH₂)(CH₃)(η⁵-C₅H₅)₂, Ta(η³-C₃H₅) (η⁵-C₅H₅)₂, Ta(CH₃)₃(η⁵-C₅H₅)₂, Ta(CH₃)₄(η⁵-C₅(CH₃)₅), Ta(η⁵-C₅(CH₃)₅)₂H₃, Ti(COCH₃)(η⁵-C₅H₅)₂Cl, Ti(η⁵-C₅H₅)Cl₂, Ti(η⁵-C₅H₅)Cl₃, Ti(η⁵-C₅H₅)₂Cl₂, Ti(η⁵-C₅(CH₃)₅)Cl₃, Ti(CH₃)(η⁵-C₅H₅)₂Cl, Ti(η⁵-C₉H₇)₂Cl₂, Ti((η⁵-C₅(CH₃)₅)₂Cl, Ti((η⁵-C₅(CH₃)₅)₂Cl₂, Ti(η⁵-C₅H₅)₂(μ-Cl)₂, Ti(η⁵-C₅H₅)₂(CO)₂, Ti(CH₃)₃(η⁵-C₅H₅), Ti(CH₃)₂(η⁵-C₅H₅)₂, Ti(CH₃)₄, Ti(η⁵-C₅H₅)(η⁷-C₇H₇), Ti(η⁵-C₅H₅)(η⁸-C₈H₈), Ti(C₅H₅)₂(η⁵-C₅H₅)₂, Ti((C₅H₅)₂)₂(η-H)₂, Ti(η⁵-C₅(CH₃)₅)₂, Ti(η⁵-C₅(CH₃)₅)₂(H)₂, Ti(CH₃)₂(η⁵-C₅(CH₃)₅)₂, WF₆, or W(CO)₆, the reducing gas comprises H₂, plasma-excited H₂, or BH₃, or a combination of two or more thereof, and the nitriding gas comprises NH₃, plasma excited NH₃, plasma-excited N₂, NH(CH₃)₂, N₂H₄, or N₂H₃CH₃, or a combination of two or more thereof.

21. The method of claim 14, wherein the cobalt precursor comprises Co₂(CO)₈, CoCp(CO)₂, Co(CO)₃(NO), Co₂(CO)₆(HCCtBu), Co(acac)₂, Co(Cp)₂, Co(Me₅Cp)₂), Co(EtCp)₂, cobalt(II) hexafluoroacetylacetonate hydrate, cobalt tris(2,2,6,6-tetramethyl-3,5-heptanedionate), cobalt(III) acetylacetonate, or bis(N,N′-diisopropylacetamidinato)cobalt, or tricarbonyl allyl cobalt, or a combination of two or more thereof.

22. A method for fabricating a semiconductor device, the method comprising:
providing a substrate containing a dielectric film having a recessed feature;
forming a cobalt metal nitride barrier film in the recessed feature; and
forming bulk Cu metal over the cobalt metal nitride barrier film in the recessed feature.

23. The method of claim 22, wherein forming the bulk Cu comprises:
plating bulk Cu metal in the recessed feature.

24. The method of claim 22, wherein forming the bulk Cu metal comprises:
forming a Cu seed layer in the recessed feature, and
plating bulk Cu metal onto the Cu seed layer.

25. The method of claim 22, further comprising;
depositing a cobalt film containing Co metal or Co nitride on the cobalt metal nitride barrier film prior to forming the bulk Cu metal.

26. A method for fabricating a semiconductor device, the method comprising:
providing a substrate containing a dielectric film having a recessed feature;
forming a cobalt metal nitride barrier film in the recessed feature;
forming a Ru metal film over the cobalt metal nitride barrier film; and
forming bulk Cu metal over the Ru metal film in the recessed feature.

27. The method of claim 26, wherein forming the bulk Cu comprises:
plating bulk Cu metal in the recessed feature.

28. The method of claim 26, wherein forming the bulk Cu comprises:
forming a Cu seed layer in the recessed feature, and
plating bulk Cu onto the Cu seed layer.

29. The method of claim 22, further comprising;
depositing a Co metal layer on the Ru metal film prior to forming the bulk Cu metal.
